(19) United States
(12) Patent Application Publication
(10) Pub. No.: US 2023/0382713 A1
(43) Pub. Date: Nov. 30, 2023

(54) MICRO-ELECTRO-MECHANICAL SYSTEM (MEMS) DEVICE and fabrication method thereof

(71) Applicant: Vanguard International Semiconductor Corporation, Hsinchu (TW)

(72) Inventors: RAMACHANDRAMURTHY PRADEEP YELEHANKA, Singapore (SG); RAKESH CHAND, Singapore (SG); HUP FONG TAN, Singapore (SG); ROHIT PULIKKAL KIZHAKKEYIL, Singapore (SG); WAI MUN CHONG, Singapore (SG)

(73) Assignee: Vanguard International Semiconductor Corporation, Hsinchu (TW)

(21) Appl. No.: 17/826,181

(22) Filed: May 27, 2022

(51) Int. Cl. B81B 3/00; B81C 3/00

(52) U.S. Cl. CPC B81B 3/0021; B81C 3/001; B81C 2203/0792; B81B 2201/025; B81C 2203/038

(57) ABSTRACT

A micro-electro-mechanical system (MEMS) device includes a first substrate, an interconnect layer, a MEMS device layer, a stopper and a second substrate. The interconnect layer is disposed on the first substrate and includes a plurality of conductive layers and a plurality of dielectric layer stacked alternately. The MEMS device layer is bonded on the interconnect layer and includes a proof mass. The stopper is disposed directly under the proof mass and spaced apart from the proof mass, where the stopper is surrounded by a portion of the interconnect layer, and the stopper includes a bottom portion constructed of one of the plurality of conductive layers, and a silicon-based layer disposed on the bottom portion. The second substrate includes a cavity and is bonded on the MEMS device layer.

### BACKGROUND OF THE INVENTION

### 1. Field of the Invention

The present disclosure relates generally to micro-electro-mechanical system (MEMS) devices, and more particularly to MEMS devices including a stopper that avoids stiction between a MEMS device layer and an interconnect layer, and fabrication methods of the MEMS devices.

### 2. Description of the Prior Art

Micro-electro-mechanical systems (MEMS) devices are microscopic devices that integrate mechanical and electrical components to sense physical quantities and/or to interact with the surrounding environment. In recent years, MEMS devices have become increasingly common in microelectronics industries. For example, the MEMS devices are used as micro-sensors such as motion sensors, pressure sensors, acceleration sensors, etc., and have become widespread in many electronic products.

MEMS devices usually consist of a microprocessor that processes data and several components such as micro-sensors that interact with the surrounding environment. The micro-sensors of the MEMS devices have a large surface area to volume ratio, so that forces produced by ambient electromagnetism (e.g., electrostatic charges and magnetic moments), and fluid dynamics (e.g., surface tension and viscosity) are more important design considerations than mechanical devices with larger scale. For example, stiction may be produced between a movable part and a metal surface of the conventional MEMS devices, thereby reducing the production yield and the reliability of the conventional MEMS devices.

### SUMMARY OF THE INVENTION

In view of this, embodiments of the present disclosure provide improved MEMS devices and fabrication methods thereof to overcome the aforementioned problems of the conventional MEMS devices. The MEMS devices of the present disclosure include a stopper disposed directly under a proof mass of a MEMS device layer and spaced apart from the proof mass. The stopper avoids stiction between the proof mass and an interconnect layer, thereby improving the reliability and the production yield of the MEMS devices.

According to one embodiment of the present disclosure, a micro-electro-mechanical system (MEMS) device is provided and includes a first substrate, an interconnect layer, a MEMS device layer, a stopper and a second substrate. The interconnect layer is disposed on the first substrate and includes a plurality of conductive layers and a plurality of dielectric layer stacked alternately. The MEMS device layer is bonded on the interconnect layer and includes a proof mass. The stopper is disposed directly under the proof mass and spaced apart from the proof mass, where the stopper is surrounded by a portion of the interconnect layer, and the stopper includes a bottom portion constructed of one of the plurality of conductive layers, and a silicon-based layer disposed on the bottom portion. The second substrate includes a cavity and is bonded on the MEMS device layer.

According to one embodiment of the present disclosure, a method of fabricating a MEMS device is provided and includes the following steps. A first substrate is provided and an interconnect layer is formed on the first substrate, where the interconnect layer includes a plurality of conductive layers and a plurality of dielectric layer stacked alternately. A stopper is formed on the first substrate, where the stopper is surrounded by a portion of the interconnect layer, and the stopper includes a bottom portion formed from one of the plurality of conductive layers, and a silicon-based layer formed on the bottom portion. A MEMS device layer is formed on the interconnect layer, where the MEMS device layer includes a proof mass directly above the stopper and spaced apart from the stopper. In addition, a second substrate including a cavity is provided to bond with the MEMS device layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 shows a schematic cross-sectional diagram of a MEMS device according to one embodiment of the present disclosure.

FIG. 2 shows a schematic cross-sectional diagram of a MEMS device according to another embodiment of the present disclosure.

FIG. 3 shows a schematic cross-sectional diagram of a MEMS device according to further another embodiment of the present disclosure.

FIG. 4, FIG. 5 and FIG. 6 show schematic cross-sectional diagrams of several stages of a method of fabricating a MEMS device according to one embodiment of the present disclosure.

FIG. 7 and FIG. 8 show schematic cross-sectional diagrams of several stages of a method of fabricating a MEMS device according to another embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element (s) or feature (s) as illustrated in the figures. The spatially relative terms are intended to encompass different orientations of the device in use or operation in addition to the orientation depicted in the figures. For example, if the device in the figures is turned over, elements described as “below” and/or “under” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first”, “second”, and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that may vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure is directed to MEMS devices and fabrication methods thereof. The MEMS devices include an inertial measurement unit (IMU), such as an accelerometer, a gyroscope, etc. A MEMS device layer of the MEMS devices includes a proof mass and the MEMS device layer is bonded on an interconnect layer. The interconnect layer includes multiple conductive layers and multiple dielectric layer stacked alternately. According to embodiments of the present disclosure, the MEMS devices include a stopper disposed directly under and spaced apart from the proof mass. The stopper includes a bottom portion constructed of one of the multiple conductive layers, and a silicon-based layer disposed on the bottom portion. The silicon-based layer may be formed by a sputtering process or a plasma-enhanced chemical vapor deposition (PECVD) process, and the material of the silicon-based layer includes polysilicon, amorphous silicon or single crystal silicon. The silicon-based layer of the stopper has a rough surface and the material thereof has conductivity. The phrase “rough surface” can be interpreted as a surface that is rougher than the surface of a metal layer in an interconnect layer of the MEMS device, and the roughness of the surface can be measured based on common surface roughness parameters, such as Ra or Rq. In addition, the silicon-based layer is electrically coupled to the bottom portion, and the bottom portion may be electrically floating or coupled to the ground. Accordingly, the stopper of the MEMS devices of the present disclosure avoids stiction between the proof mass and the stopper or the interconnect layer, thereby further preventing damage to the MEMS device layer of the MEMS devices. Therefore, the reliability and the production yield of the MEMS devices of the present disclosure are improved.

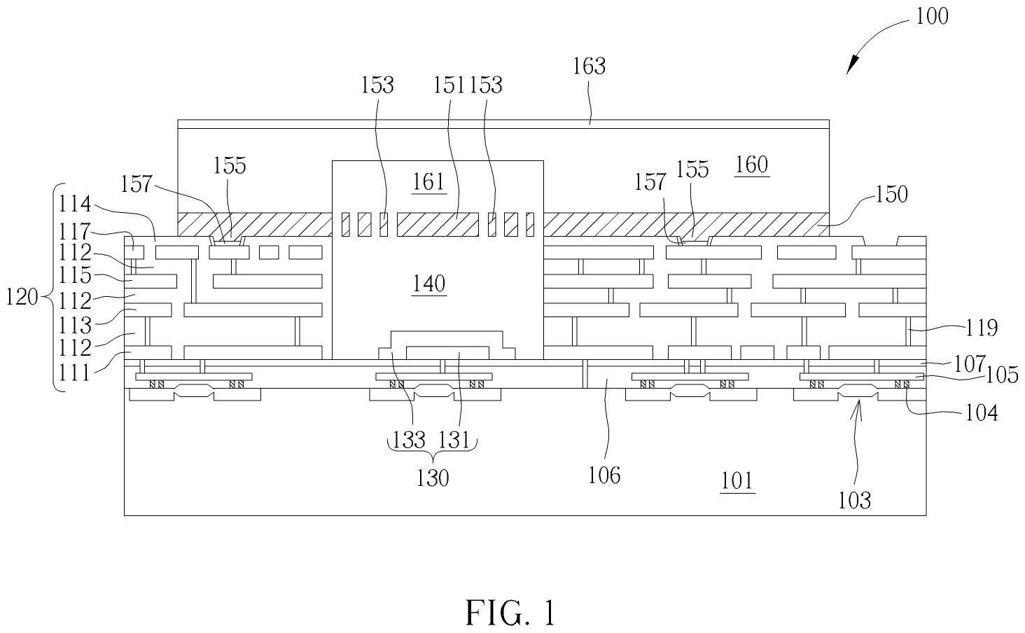

FIG. 1 shows a schematic cross-sectional diagram of a MEMS device 100 according to one embodiment of the present disclosure. Referring to FIG. 1, the MEMS device 100 includes a first substrate 101. The first substrate 101 may be a semiconductor substrate, for example a silicon (Si) wafer or other suitable semiconductor wafer. In some embodiments, the first substrate 101 may include multiple complementary metal oxide semiconductor (CMOS) transistors 103 and other semiconductor elements (not shown) formed therein. In addition, several dielectric layers 106, one or more wire layers 105, multiple vias 104 and a passivation layer 107 are formed on the first substrate 101 to cover the CMOS transistors 103. The wire layer 105 is formed between the dielectric layers 106 and is electrically coupled to the CMOS transistors 103 through the vias 104. The vias 104 are formed in the dielectric layers 106. The passivation layer 107 is formed on the top dielectric layer 106. In some other embodiments, the first substrate 101 may be an interposer without the CMOS transistors 103 formed therein and with several through substrate vias (TSVs) formed therein for electrically connecting the components disposed above and under the first substrate 101 with each other.

As shown in FIG. 1, the MEMS device 100 further includes an interconnect layer 120 disposed over the first substrate 101 and on the passivation layer 107. The interconnect layer 120 includes multiple conductive layers, for example, a first metal layer 111, a second metal layer 113, a third metal layer 115 and a fourth metal layer 117, but not limited thereto. The interconnect layer 120 further includes multiple dielectric layers, for example, three inter-metal-dielectric (IMD) layers 112 and a top dielectric layer 114, but not limited thereto. The multiple conductive layers and the multiple dielectric layers of the interconnect layer 120 are stacked alternately. In some embodiments, the first metal layer 111 is a lowest conductive layer, the second metal layer 113 and the third metal layer 115 are middle conductive layers, and the fourth metal layer 117 is a top conductive layer. The number of the conductive layers and the number of the dielectric layers of the interconnect layer 120 may be respectively less than or greater than four, which are dependent on the requirements of the MEMS device 100. The materials of the conductive layers of the interconnect layer 120 include aluminum (Al), copper (Cu), aluminum-copper (AlCu), titanium (Ti), titanium nitride (TiN), other suitable conductive materials, or a combination thereof. The materials of the dielectric layers of the interconnect layer 120 include silicon oxide, silicon nitride, silicon oxynitride, other suitable dielectric materials, or a combination thereof. Moreover, the interconnect layer 120 includes multiple vias 119 formed in the dielectric layers for electrically connecting the conductive layers with each other. In addition, several vias are formed in the passivation layer 107 and the dielectric layer 106 for electrically connecting the first metal layer 111 to the wire layer 105, so that the interconnect layer 120 is electrically coupled to the CMOS transistors 103 in the first substrate 101.

Still referring to FIG. 1, in one embodiment, the interconnect layer 120 includes a concave portion 140 that passes through all the conductive layers and all the dielectric layers of the interconnect layer 120. The bottom surface of the concave portion 140 and the bottom surface of the first metal layer 111 (the lowest conductive layer) may be on the same plane. The concave portion 140 is surrounded by a portion of the interconnect layer 120. Moreover, the MEMS device 100 includes a stopper 130 disposed in the concave portion 140 and surrounded by the portion of the interconnect layer 120. In this embodiment, the stopper 130 includes a bottom portion 131 that is constructed of one of the multiple conductive layers of the interconnect layer 120, for example a portion of the first metal layer 111, i.e., a portion of the lowest conductive layer of the interconnect layer 120. The stopper 130 further includes a silicon-based layer 133 that may be conformally disposed on the bottom portion 131. The silicon-based layer 133 is formed to have a rough surface and the material of the silicon-based layer 133 has conductivity. The material of the silicon-based layer 133 may be polysilicon, amorphous silicon or single crystal silicon, for example doped silicon or doped polysilicon. The silicon-based layer 133 may be formed by a deposition process such as a sputtering process or a plasma-enhanced chemical vapor deposition (PECVD) process. In addition, the silicon-based layer 133 is electrically coupled to the bottom portion 131, and the bottom portion 131 may be electrically floating or coupled to the ground. In some embodiments, the bottom portion 131 is electrically coupled to the ground for effectively avoiding charge accumulation on the stopper 130.

As shown in FIG. 1, the MEMS device 100 further includes a MEMS device layer 150 bonded on the interconnect layer 120. The MEMS device layer 150 may be formed of a thinned silicon wafer, a polysilicon layer or other suitable semiconductor layer. In some embodiments, the MEMS device layer 150 includes a proof mass 151, several suspension beams 153 adjacent to the proof mass 151, several protruding portions 155 towards the interconnect layer 120, and several conductive layer 157 respectively on the surfaces of the protruding portions 155. In the embodiment, the MEMS device layer 150 is bonded with the fourth metal layer 117 (the top conductive layer) of the interconnect layer 120 through the conductive layer 157 and the protruding portions 155. The material of the conductive layer 157 may be a metal, for example, germanium (Ge), aluminum (Al), copper (Cu), aluminum-copper (AlCu), or other conductive or semiconductive materials. The MEMS device layer 150 may be bonded on the interconnect layer 120 by eutectic bonding between the conductive layer 157 and the fourth metal layer 117 (the top conductive layer). The stopper 130 is disposed directly under the proof mass 151 and spaced apart from the proof mass 151 through the concave portion 140 of the interconnect layer 120.

Moreover, the MEMS device 100 includes a second substrate 160 bonded on the MEMS device layer 150. The second substrate 160 may be a silicon (Si) wafer or other suitable semiconductor wafer. The material of the second substrate 160 includes a single crystal semiconductor material, such as silicon, sapphire or other suitable semiconductor materials, for example elementary semiconductors such as such as Ge; compound semiconductors such as GaN, SiC, GaAs, GaP, InP, InAs, and/or InSb; alloy semiconductors such as SiGe, GaAsP, AlInAs, AIN, AlGaAs, GalnAs, GaInP, GaInAsP, or a combination thereof. As shown in FIG. 1, in one embodiment, a cavity 161 is formed at a lower surface of the second substrate 160, and the proof mass 151 and the suspension beams 153 of the MEMS device layer 150 are disposed corresponding to and directly under the cavity 161 of the second substrate 160. In addition, a metal layer 163 may be formed on an upper surface of the second substrate 160. The material of the metal layer 163 is, for example, aluminum (Al), copper (Cu), aluminum-copper (AlCu) or other suitable metal materials. The metal layer 163 may be used as a shielding layer or a protective layer.

According to the embodiment of the present disclosure, the bottom portion 131 of the stopper 130 is constructed of a portion of the first metal layer 111 (the lowest conductive layer) of the interconnect layer 120, so that the space between the proof mass 151 and the stopper 130 provided by the concave portion 140 is larger to effectively avoid stiction between the proof mass 151 and the stopper 130 and/or damage to the MEMS device layer 150. In addition, the silicon-based layer 133 of the stopper 130 is formed to have a rough surface, the silicon-based layer 133 is electrically coupled to the bottom portion 131, and the bottom portion 131 may be electrically floating or coupled to the ground. The rough surface of the stopper 130 effectively avoids stiction between the proof mass 151 and the stopper 130 during the operation of the MEMS device 100 or when a mechanical shock is applied to the MEMS device 100. Moreover, there is no or less charge accumulation on the surface of the stopper 130 because of the conductivity of the stopper 130, thereby further avoiding stiction between the proof mass 151 and the stopper 130. Therefore, the reliability and the production yield of the MEMS device 100 of the present disclosure are improved.

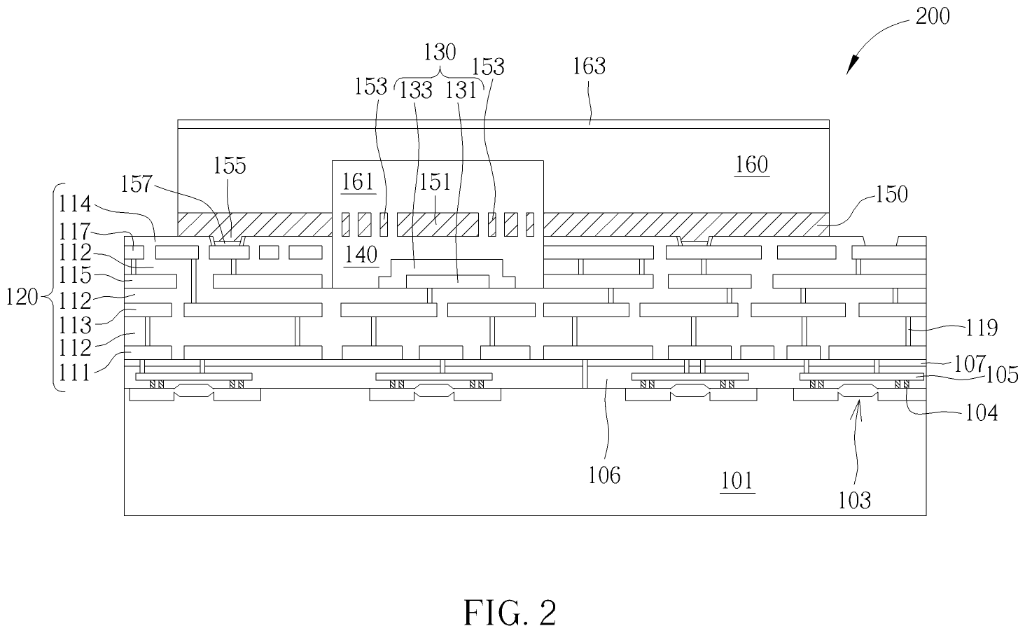

FIG. 2 shows a schematic cross-sectional diagram of a MEMS device 200 according to another embodiment of the present disclosure. The difference between the MEMS device 200 and the MEMS device 100 of FIG. 1 is that the bottom portion 131 of the stopper 130 of the MEMS device 200 is constructed of a portion of the third metal layer 115, i.e., a portion of a middle conductive layer of the interconnect layer 120. A concave portion 140 of the interconnect layer 200 of the MEMS device 200 is formed to pass through the top dielectric layer 114, the fourth metal layer 117 (the top conductive layer), the inter-metal-dielectric (IMD) layer 112, and the third metal layer 115 (the middle conductive layer) of the interconnect layer 120. The bottom surface of the concave portion 140 and the bottom surface of the third metal layer 115 (the middle conductive layer) may be on the same plane. The details of other components of the MEMS device 200 may refer to the aforementioned descriptions of the MEMS device 100, and not repeated herein.

In this embodiment, the space between the proof mass 151 and the stopper 130 provided by the concave portion 140 is large enough to avoid stiction between the proof mass 151 and the stopper 130 and/or damage to the MEMS device layer 150. In addition, the silicon-based layer 133 of the stopper 130 is formed to have a rough surface, the silicon-based layer 133 is electrically coupled to the bottom portion 131, and the bottom portion 131 may be electrically floating or coupled to the ground. The rough surface of the stopper 130 effectively avoids stiction between the proof mass 151 and the stopper 130. Moreover, there is no or less charge accumulation on the surface of the stopper 130, thereby further avoiding stiction between the proof mass 151 and the stopper 130. Therefore, the reliability and the production yield of the MEMS device 200 of the present disclosure are improved.

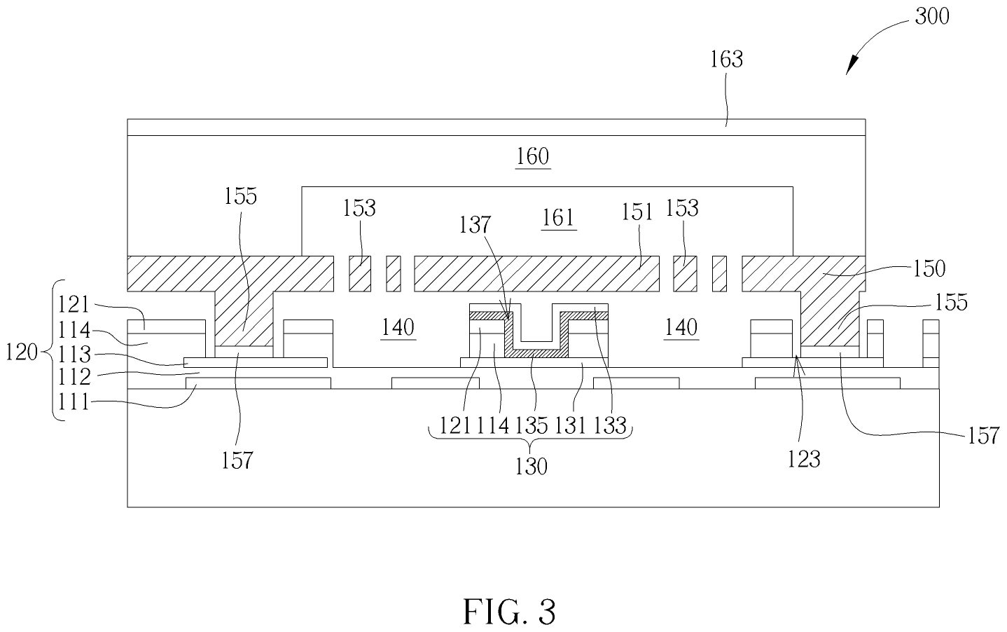

FIG. 3 shows a schematic cross-sectional diagram of a MEMS device 300 according to further another embodiment of the present disclosure. As shown in FIG. 3, in one embodiment, the first substrate 101 of the MEMS device 300 may not have CMOS transistors formed therein. In addition, the interconnect layer 120 of the MEMS device 300 may include a first metal layer 111, an inter-metal-dielectric (IMD) layer 112, a second metal layer 113, a top dielectric layer 114, and a passivation layer 121, but not limited thereto. The interconnect layer 120 of the MEMS device 300 may include more than two conductive layers and more than two dielectric layers stacked alternately. In this embodiment, the first metal layer 111 is a lowest conductive layer, and the second metal layer 113 is a top conductive layer. The IMD layer 112 is disposed between the first metal layer 111 and the second metal layer 113. The top dielectric layer 114 is disposed on the second metal layer 113 (the top conductive layer), and the passivation layer 121 is disposed on the top dielectric layer 114. The material of the passivation layer 121 is different from the materials of the IMD layer 112 and the top dielectric layer 114. For example, the passivation layer 121 may be formed of silicon nitride, and the IMD layer 112 and the top dielectric layer 114 may be formed of silicon oxide. A stopper 130 is disposed directly under and spaced apart from the proof mass 151 of the MEMS device layer 150. The stopper 130 is surrounded by a portion of the interconnect layer 120 and disposed in a concave portion 140 of the interconnect layer 120, where the concave portion 140 is surrounded by the portion of the interconnect layer 120. The concave portion 140 is formed to pass through the passivation layer 121, the top dielectric layer 114 and the second metal layer 113 (the top conductive layer). The bottom surface of the concave portion 140 and the bottom surface of the second metal layer 113 may be on the same plane.

As shown in FIG. 3, in this embodiment, the stopper 130 includes a bottom portion 131, a portion of the top dielectric layer 114 and a portion of the passivation layer 121 stacked in sequence on the bottom portion 131, a barrier layer 135 and a silicon-based layer 133. The bottom portion 131 is constructed of a portion of the second metal layer 113 (the top conductive layer) of the interconnect layer 120. The stopper 130 further includes a through hole 137 in the portion of the top dielectric layer 114 and the portion of the passivation layer 121. Both the barrier layer 135 and the silicon-based layer 133 are conformally disposed on the portion of the passivation layer 121 and in the through hole 137 in sequence. The silicon-based layer 133 is conformally disposed on the portion of the passivation layer 121 and in the through hole 137. The barrier layer 135 is conformally disposed between the silicon-based layer 133 and the portion of the passivation layer 121, between the silicon-based layer 133 and the portion of the top dielectric layer 114, and between the silicon-based layer 133 and the bottom portion 131. The material of the barrier layer 135 may be Ti, TiN or a combination thereof.

In addition, the MEMS device layer 150 of the MEMS device 300 is bonded with the second metal layer 113 (the top conductive layer) of the interconnect layer 120 through the conductive layer 157 and the protruding portions 155. In this embodiment, there are several through holes 123 formed in the passivation layer 121 and the top dielectric layer 114 to expose some portions of the second metal layer 113 for bonding with the conductive layer 157 of the MEMS device layer 150. The protruding portions 155 and the conductive layer 157 of the MEMS device layer 150 are disposed in the through holes 123, and the conductive layer 157 and the portions of the second metal layer 113 are bonded by eutectic bonding. The details of other components of the MEMS device 300 may refer to the aforementioned descriptions of the MEMS device 100, and not repeated herein.

In the embodiment of the MEMS device 300, the silicon-based layer 133 of the stopper 130 is formed to have a rough surface. The rough surface of the stopper 130 effectively avoids stiction between the proof mass 151 and the stopper 130. In addition, the silicon-based layer 133 is electrically coupled to the bottom portion 131, and the bottom portion 131 may be electrically floating or coupled to the ground. There is no or less charge accumulation on the stopper 130, thereby further avoiding stiction between the proof mass 151 and the stopper 130. Furthermore, the barrier layer 135 and the silicon-based layer 133 are conformally disposed on the passivation layer 121 and in the through hole 137 to provide the stopper 130 with concave and convex profiles that more effectively avoids stiction between the proof mass 151 and the stopper 130. In addition, the barrier layer 135 prevents ion diffusion between the silicon-based layer 133 and the bottom portion 131. Therefore, the reliability and the production yield of the MEMS device 300 of the present disclosure are improved.

Moreover, in some embodiments of the present disclosure, the proof mass 151 of the MEMS devices may be vertically aligned with the COMS transistors 103 of the first substrate 101. In addition, the proof mass 151 of the MEMS devices of the present disclosure is disposed above the interconnect layer 120, and the proof mass 151 does not include the metal layers of the interconnect layer 120.

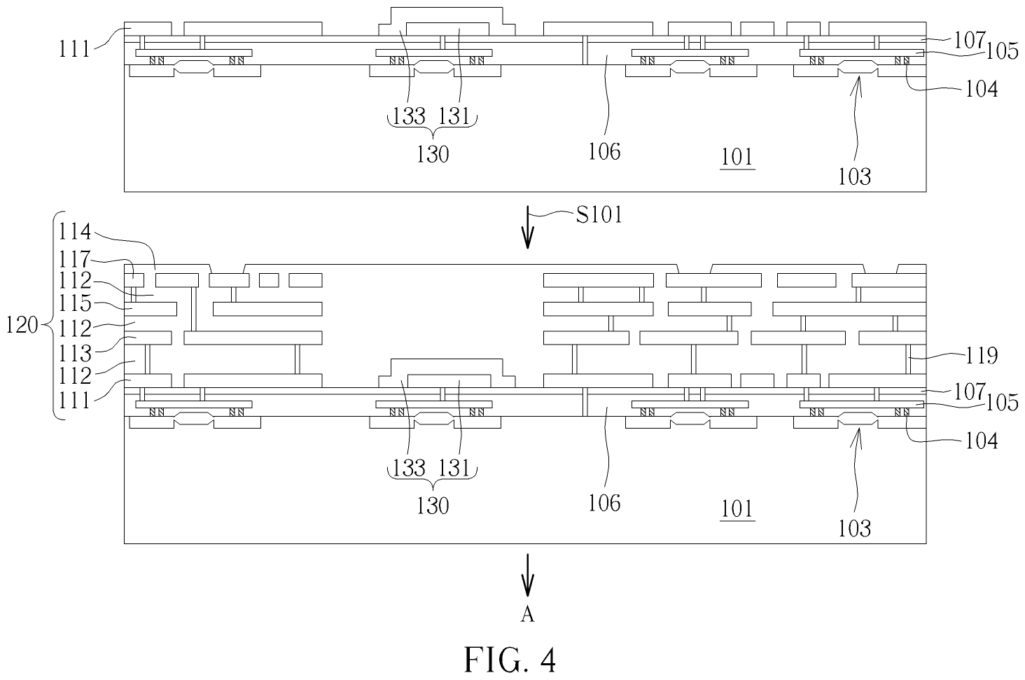

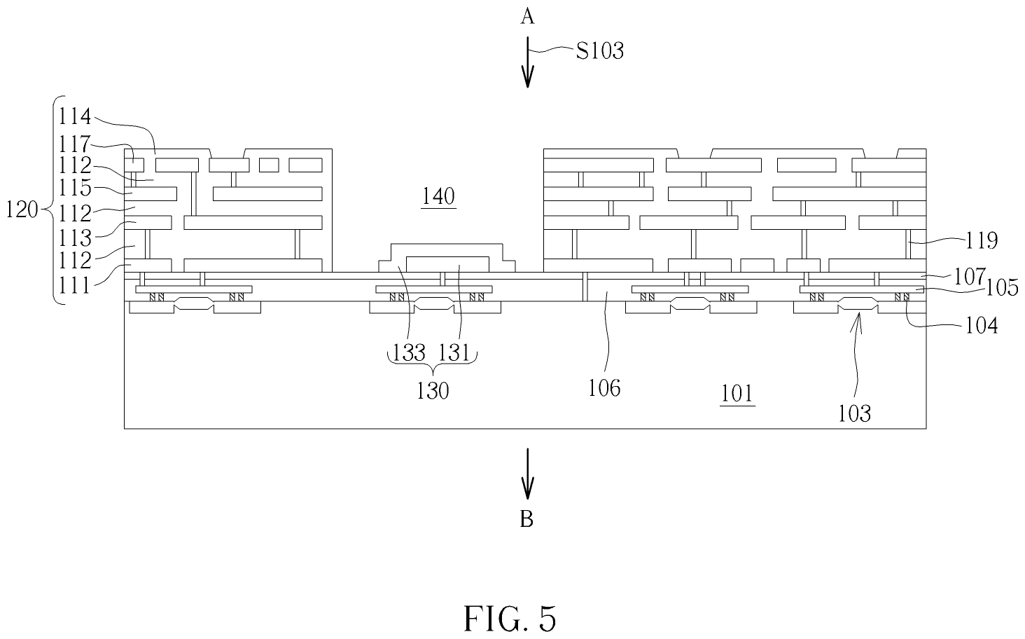

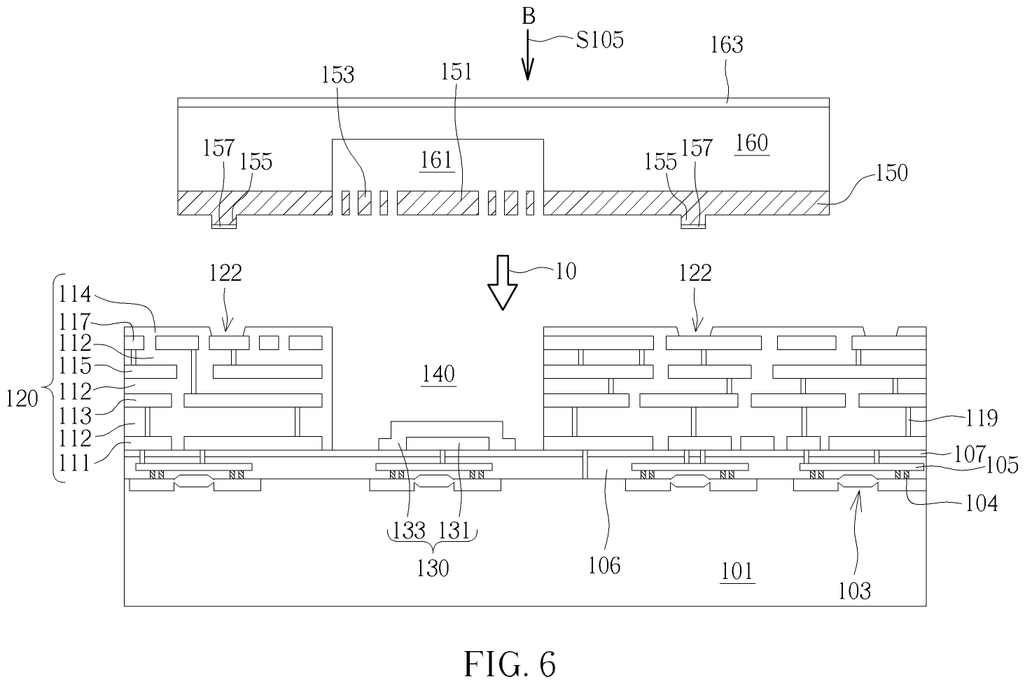

FIG. 4, FIG. 5 and FIG. 6 show schematic cross-sectional diagrams of several stages of a method of fabricating a MEMS device according to one embodiment of the present disclosure. Referring to FIG. 4, firstly, a first substrate 101 is provided. The first substrate 101 includes multiple CMOS transistors 103 formed therein. The first substrate 101 further includes a wire layer 105, several dielectric layers 106, multiple vias 104 and a passivation layer 107 formed on the CMOS transistors 103. The details of the first substrate 101 may refer to the aforementioned description of the MEMS device 100 of FIG. 1, and not repeated herein. Then, a first metal layer 111 (the lowest conductive layer) of an interconnect layer 120 is formed on the passivation layer 107. The first metal layer 111 is formed by depositing and patterning, and a portion of the first metal layer 111 (the lowest conductive layer) is used to be a bottom portion 131 of a stopper 130. A silicon-based layer 133 is conformally formed on the bottom portion 131 to complete the stopper 130. The silicon-based layer 133 may be formed by depositing a silicon-based material layer using a deposition process such as a sputtering process or a PECVD process, and then patterning the silicon-based material layer by an etching process. The material of the silicon-based layer 133 may be polysilicon, amorphous silicon or single crystal silicon, for example doped silicon or doped polysilicon. The silicon-based layer 133 is formed to have a rough surface and conductivity, thereby avoiding stiction between a proof mass 151 of a MEMS device layer 150 and the stopper 130 in the MEMS device.

Next, still referring to FIG. 4, at step S101, other layers of the interconnect layer 120 are formed on the first metal layer 111 and the stopper 130. The interconnect layer 120 includes multiple conductive layers and multiple dielectric layers stacked alternately. The details of the interconnect layer 120 may refer to the aforementioned description of the MEMS device 100 of FIG. 1, and not repeated herein. In this embodiment, the stopper 130 is covered with a portion of the multiple dielectric layers of the interconnect layer 120, i.e., some portions of the IMD layers 112 and the top dielectric layer 114. Then, the top dielectric layer 114 is etched to form several holes 122 to expose some portions of the fourth metal layer 117 (the top conductive layer) of the interconnect layer 120.

Next, referring to FIG. 5, at step S103, the portions of the IMD layers 112 and the top dielectric layer 114 covering the stopper 130 are removed by an etching process to form a concave portion 140, thereby exposing the stopper 130 through the concave portion 140. In this embodiment, the concave portion 140 passes through all the conductive layers and all the dielectric layers of the interconnect layer 120. The bottom surface of the concave portion 140 and the bottom surface of the first metal layer 111 (the lowest conductive layer) may be on the same plane. In addition, the concave portion 140 is surrounded by the remaining portion of the interconnect layer 120. The stopper 130 is disposed in the concave portion 140 and also surrounded by the remaining portion of the interconnect layer 120.

In some embodiments, the silicon-based layer 133 may be formed at step S103 after all layers of the interconnect layer 120 are formed over the bottom portion 131 and the portion of the interconnect layer 120 covering the bottom portion 131 is removed to form the concave portion 140 to expose the bottom portion 131. Then, the silicon-based layer 133 is formed on the bottom portion 131 by deposition and patterning processes.

In some other embodiments, the bottom portion 131 of the stopper 130 may be formed by using a portion of a middle conductive layer of the interconnect layer 120, for example a portion of the second metal layer 113, or a portion of the third metal layer 115. In these embodiments, the first metal layer 111, the IMD layer 112 and the second metal layer 113 of the interconnect layer 120 are formed on the passivation layer 107, and a portion of the second metal layer 113 is used to be the bottom portion 131. Alternatively, the first metal layer 111, the second metal layer 113, the third metal layer 115 and the IMD layers 112 of the interconnect layer 120 are formed on the passivation layer 107, and then a portion of the third metal layer 115 is used to be the bottom portion 131. In some embodiments, the silicon-based layer 133 may be firstly formed on the bottom portion 131 to complete the stopper 130. Then, the other dielectric layers and conductive layer(s) of the interconnect layer 120 are formed above the second metal layer 113 or the third metal layer 115 (the middle conductive layer) to cover the stopper 130. Thereafter, the portion of the dielectric layers of the interconnect layer 120 covering the stopper 130 is removed by an etching process to form the concave portion 140, where the stopper 130 is exposed through the concave portion 140. Alternatively, the silicon-based layer 133 of the stopper may be formed on the bottom portion 131 after the concave portion 140 is formed. In these embodiments, the bottom surface of the concave portion 140 and the bottom surface of the second metal layer 113 or the third metal layer 115 (the middle conductive layer) may be on the same plane.

Next, referring to FIG. 6, at step S105, a MEMS device layer 150 bonded with a second substrate 160 is provided. The second substrate 160 includes a cavity 161 formed on the lower surface thereof. Moreover, a metal layer 163 is formed on the upper surface of the second substrate 160. The MEMS device layer 150 may be formed by bonding a device wafer on the lower surface of the second substrate 160, thinning the device wafer to form a device layer, and patterning the device layer to form the MEMS device layer 150. The MEMS device layer 150 includes a proof mass 151, several suspension beams 153 adjacent to the proof mass 151, several protruding portions 155 towards the interconnect layer 120, and conductive layer 157 respectively formed on the protruding portions 155. The suspension beams 153 and the proof mass 151 are disposed corresponding to the cavity 161 of the second substrate 160. Then, the MEMS device layer 150 is bonded on the interconnect layer 120 by a bonding process 10 to complete the MEMS device 100 of FIG. 1. After the bonding process 10, the protruding portions 155 of the MEMS device layer 150 are disposed in the holes 122 of the top dielectric layer 114, and the conductive layer 157 are bonded with the fourth metal layer 117 (the top conductive layer) of the interconnect layer 120 by eutectic bonding. In addition, the MEMS device layer 150 is spaced apart from the stopper 130 by the concave portion 140.

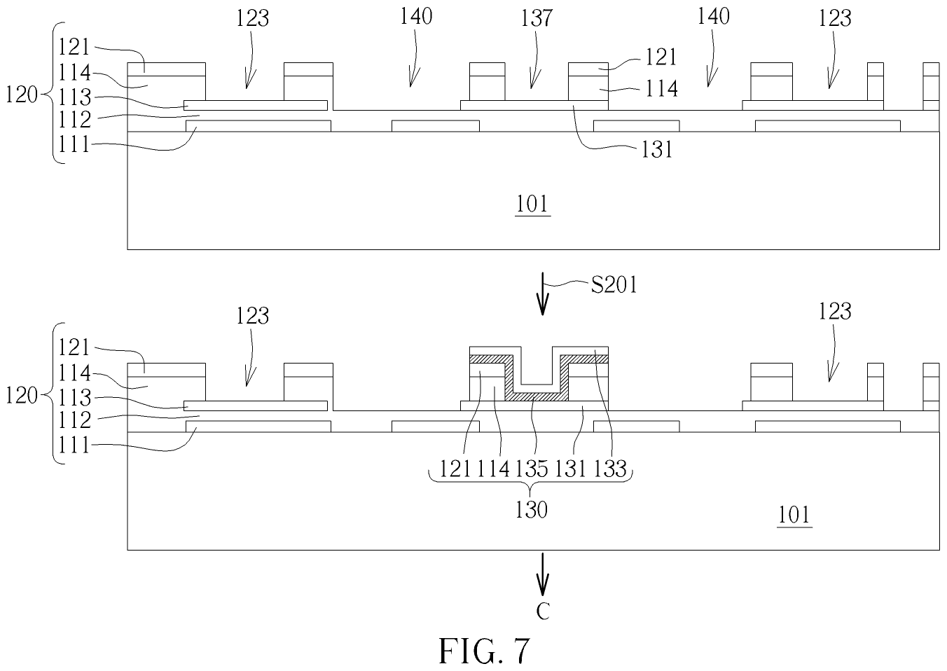

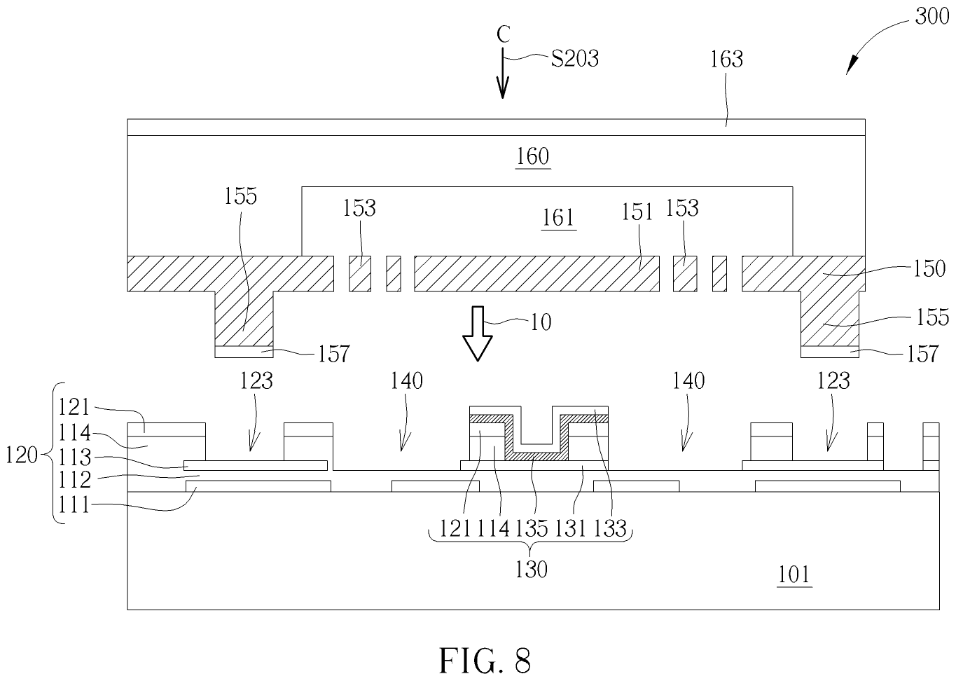

FIG. 7 and FIG. 8 show schematic cross-sectional diagrams of several stages of a method of fabricating a MEMS device according to another embodiment of the present disclosure. Referring to FIG. 7, firstly, a first substrate 101 is provided. In some embodiments, the first substrate 101 may be a Si wafer without CMOS transistors formed therein. An interconnect layer 120 is formed on the first substrate 101. The interconnect layer 120 may include a first metal layer 111, an IMD layer 112, a second metal layer 113, a top dielectric layer 114 and a passivation layer 121 stacked in sequence on the first substrate 101, but not limited thereto. Then, the interconnect layer 120 is patterned to form a concave portion 140 by photolithography and etching processes, and a portion of the passivation layer 121 and a portion of the top dielectric layer 114 are remained in the concave portion 140 for forming a stopper. The concave portion 140 is surrounded by a portion of the interconnect layer 120. The bottom surface of the concave portion 140 and the bottom surface of the second metal layer 113 may be on the same plane. Thereafter, as shown in FIG. 7, the portion of the passivation layer 121 and the portion of the top dielectric layer 114 remained in the concave portion 140 are etched to form a through hole 137. A portion of the second metal layer 113 (the top conductive layer) is used to be a bottom portion 131 of the stopper, and a portion of the bottom portion 131 is exposed by the through hole 137. Moreover, as shown in FIG. 7, the portion of the interconnect layer 120 surrounding the concave portion 140 is also etched to form several through holes 123 to expose some portions of the second metal layer 113 for bonding with a MEMS device layer.

Next, still referring to FIG. 7, at step S201, a barrier layer 135 is conformally formed on the portion of the passivation layer 121 and in the through hole 137 by a depositing process. The material of the barrier layer 135 may be Ti, TiN, other suitable barrier materials or a combination thereof. Then, a silicon-based layer 133 is conformally formed on the barrier layer 135 by a sputtering process or a PECVD process. The silicon-based layer 133 is also conformally disposed over the portion of the passivation layer 121 and in the through hole 137. The material of the silicon-based layer 133 may be polysilicon, amorphous silicon or single crystal silicon. For example, the silicon-based layer 133 may be a doped-Si layer or a doped polysilicon layer that has conductivity. The deposited barrier layer 135 and the deposited silicon-based layer 133 may be patterned by an etching process to remove some portions thereof on the bottom surface of the concave portion 140 and on the outside sidewalls of the passivation layer 121 and the top dielectric layer 114 in the concave portion 140 to complete the stopper 130.

Then, referring to FIG. 8, at step S203, a MEMS device layer 150 bonded with a second substrate 160 is provided. The second substrate 160 includes a cavity 161 formed on the lower surface thereof. Moreover, a metal layer 163 is formed on the upper surface of the second substrate 160. The MEMS device layer 150 includes a proof mass 151, several suspension beams 153 adjacent to the proof mass 151, several protruding portions 155 towards the interconnect layer 120, and conductive layer 157 respectively formed on the protruding portions 155. The suspension beams 153 and the proof mass 151 are disposed corresponding to the cavity 161 of the second substrate 160. Then, the MEMS device layer 150 is bonded on the interconnect layer 120 by a bonding process 10 to complete the MEMS device 300 of FIG. 3. After the bonding process 10, the protruding portions 155 of the MEMS device layer 150 are disposed in the through holes 123 of the interconnect layer 120, and the conductive layer 157 are bonded with the second metal layer 113 (the top conductive layer) of the interconnect layer 120 by eutectic bonding.

The MEMS device layer 150 of the MEMS devices 100, 200 and 300 as shown in FIG. 1, FIG. 2 and FIG. 3 are illustrated for examples, and should not be construed in a limiting sense. The MEMS devices of the present disclosure include inertial measurement units (IMU), inertial sensors, pressure sensors, micro-fluidic devices, other micro devices or a combination thereof, and the IMU includes an accelerometer, a gyroscope, other IMU devices or a combination thereof.

According to the embodiments of the present disclosure, the stopper of the MEMS devices is disposed directly under the proof mass of the MEMS device layer and spaced apart from the proof mass. The silicon-based layer of the stopper has a rough surface and has conductivity to be electrically coupled to the bottom portion of the stopper. The bottom portion of the stopper is electrically floating or coupled to the ground. Accordingly, the stopper of the MEMS devices of the present disclosure avoids charge accumulation on the stopper. Therefore, stiction between the proof mass of the MEMS device layer and the interconnect layer is effectively prevented by the stopper of the MEMS devices of the present disclosure. Furthermore, mechanical damage to the MEMS device layer is also prevented by the stopper of the MEMS devices of the present disclosure. Therefore, the reliability and the production yield of the MEMS devices of the present disclosure are improved.

In addition, the process of fabricating the stopper of the MEMS devices of the present disclosure is compatible with the fabrication of the interconnect layer. Since the stopper is fabricated during the fabrication of the interconnect layer, thereby saving the process steps of the fabrication of the MEMS devices. Moreover, according to the embodiments of the present disclosure, the bottom portion of the stopper is constructed of any one of the conductive layers of the interconnect layer, and the stopper is disposed in the concave portion of the interconnect layer. The stopper may be spaced apart from the proof mass through the concave portion of the interconnect layer. Accordingly, the gap between the proof mass and the stopper is easily controlled by selectively choosing the metal layer of the interconnect layer for the stopper, the depth of the concave portion of the interconnect layer, and the height of the stopper. The height of the stopper may be controlled by the thickness of the silicon-based layer. Furthermore, the stopper is also used as a mechanical stopper in the MEMS devices of the present disclosure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A micro-electro-mechanical system (MEMS) device, comprising:
a first substrate;
an interconnect layer disposed on the first substrate, wherein the interconnect layer comprises a plurality of conductive layers and a plurality of dielectric layer stacked alternately;
a MEMS device layer bonded on the interconnect layer, wherein the MEMS device layer comprises a proof mass;
a stopper disposed directly under the proof mass and spaced apart from the proof mass, wherein the stopper is surrounded by a portion of the interconnect layer, and the stopper comprises:
a bottom portion constructed of one of the plurality of conductive layers; and
a silicon-based layer disposed on the bottom portion; and
a second substrate including a cavity and bonded on the MEMS device layer.

2. The MEMS device of claim 1, wherein the interconnect layer comprises a concave portion surrounded by the portion of the interconnect layer, and the stopper is disposed in the concave portion.

3. The MEMS device of claim 2, wherein the bottom portion of the stopper is constructed of a portion of a lowest conductive layer of the interconnect layer, and the concave portion passes through the interconnect layer.

4. The MEMS device of claim 2, wherein the bottom portion of the stopper is constructed of a portion of a middle conductive layer of the interconnect layer, and a bottom surface of the concave portion and a bottom surface of the middle conductive layer are on the same plane.

5. The MEMS device of claim 1, wherein the silicon-based layer comprises polysilicon, amorphous silicon or single crystal silicon.

6. The MEMS device of claim 1, wherein the MEMS device layer further comprises a protruding portion towards the interconnect layer and a conductive layer on the protruding portion, and the MEMS device layer is bonded with a top conductive layer of the interconnect layer through the conductive layer and the protruding portion.

7. The MEMS device of claim 1, wherein the MEMS device layer further comprises a suspension beam adjacent to the proof mass, and the suspension beam and the proof mass are disposed corresponding to the cavity of the second substrate.

8. The MEMS device of claim 1, wherein the first substrate includes a plurality of complementary metal oxide semiconductor (CMOS) transistors therein, and the interconnect layer is electrically coupled to the plurality of CMOS transistors.

9. The MEMS device of claim 1, wherein the bottom portion of the stopper is constructed of a portion of a top conductive layer of the interconnect layer.

10. The MEMS device of claim 9, wherein the interconnect layer further comprises a top dielectric layer disposed on the top conductive layer and a passivation layer disposed on the top dielectric layer, and the stopper further comprises a portion of the top dielectric layer and a portion of the passivation layer stacked in sequence on the bottom portion, and a through hole in the portion of the top dielectric layer and the portion of the passivation layer, wherein the silicon-based layer is conformally disposed on the portion of the passivation layer and in the through hole.

11. The MEMS device of claim 10, wherein the stopper further comprises a barrier layer conformally disposed between the silicon-based layer and the portion of the passivation layer, and between the silicon-based layer and the bottom portion, and the barrier layer comprises Ti, TiN or a combination thereof.

12. A method of fabricating a micro-electro-mechanical system (MEMS) device, comprising:
providing a first substrate;
forming an interconnect layer on the first substrate, wherein the interconnect layer comprises a plurality of conductive layers and a plurality of dielectric layer stacked alternately;
forming a stopper on the first substrate, wherein the stopper is surrounded by a portion of the interconnect layer, and the stopper comprises:
a bottom portion formed from one of the plurality of conductive layers; and
a silicon-based layer formed on the bottom portion;
forming a MEMS device layer on the interconnect layer, wherein the MEMS device layer comprises a proof mass directly above the stopper and spaced apart from the stopper; and
providing a second substrate including a cavity to bond with the MEMS device layer.

13. The method of claim 12, wherein the silicon-based layer is formed by a sputtering process or a plasma-enhanced chemical vapor deposition (PECVD) process, and the silicon-based layer comprises polysilicon, amorphous silicon or single crystal silicon.

14. The method of claim 12, wherein forming the stopper comprises:
using a portion of a lowest conductive layer of the interconnect layer to be the bottom portion; and
depositing the silicon-based layer on the bottom portion.

15. The method of claim 14, wherein forming the interconnect layer comprises:
forming the plurality of dielectric layer to cover the stopper; and
removing a portion of the plurality of dielectric layers to form a concave portion passing through the interconnect layer, wherein the stopper is exposed through the concave portion, and the MEMS device layer is spaced apart from the stopper by the concave portion.

16. The method of claim 12, wherein forming the stopper comprises:
using a portion of a middle conductive layer of the interconnect layer to be the bottom portion; and
depositing the silicon-based layer on the bottom portion.

17. The method of claim 16, wherein forming the interconnect layer comprises:
forming the plurality of dielectric layer of the interconnect layer that are above the middle conductive layer to cover the stopper; and
removing a portion of the plurality of dielectric layers to form a concave portion, wherein the stopper is exposed through the concave portion, the MEMS device layer is spaced apart from the stopper by the concave portion, and a bottom surface of the concave portion and a bottom surface of the middle conductive layer are on the same plane.

18. The method of claim 12, wherein forming the stopper comprises:
using a portion of a top conductive layer of the interconnect layer to be the bottom portion;
forming a top dielectric layer and a passivation layer of the interconnect layer on the top conductive layer in sequence;
etching the top dielectric layer and the passivation layer to form a through hole, wherein a portion of the bottom portion is exposed by the through hole;
conformally depositing a barrier layer on the passivation layer and in the through hole, wherein the barrier layer comprises Ti, TiN or a combination thereof; and
conformally depositing the silicon-based layer on the barrier layer.

19. The method of claim 18, wherein etching the top dielectric layer and the passivation layer further comprises forming another through hole to expose a portion of the top conductive layer, and the MEMS device layer is bonded with the portion of the top conductive layer.

20. The method of claim 12, wherein the first substrate includes a plurality of complementary metal oxide semiconductor (CMOS) transistors formed therein, and the interconnect layer is electrically coupled to the plurality of CMOS transistors.
